(19) United States
(12) Patent Application Publication
(10) Pub. No.: US 2024/0396439 A1
(43) Pub. Date: Nov. 28, 2024

(54) CONVERTER DEVICE

(71) Applicant: ams-OSRAM International GmbH, Regensburg (DE)

(72) Inventors: Alvaro GOMEZ-IGLESIAS, Regensburg (DE); Horst VARGA, Lappersdorf (DE)

(21) Appl. No.: 18/693,365

(22) PCT Filed: Sep. 13, 2022
(86) PCT No.: PCT/EP2022/075366

§ 371 Date: Mar. 19, 2024

(30) Foreign Application Priority Data
Sep. 20, 2021 (DE) 10 2021 124 243.6

(51) Int. Cl. H02M 3/00; H01F 27/24; H01F 27/28; H02M 3/335

(52) U.S. Cl. CPC H02M 3/003; H01F 27/24; H01F 27/28; H02M 3/335

(57) ABSTRACT

A converter device has a primary coil, a secondary coil and a first semiconductor layer. The primary coil and the secondary coil are each flat, each has at least one winding and each is coaxially arranged. The primary coil is arranged on a bottom face of the first semiconductor layer and the secondary coil is arranged on a top face of the first semi-conductor layer.

The present invention relates to a converter device.

This patent application claims the priority of German patent application 10 2021 124 243.6, the disclosure content of which is hereby incorporated by reference.

Known beam directing technologies, actuators and detectors, for example avalanche photodiodes, single-photon avalanche diodes and photomultiplier tubes, and many applications in acoustics each require a high-voltage supply with relatively little current consumption. Such applications may require, for example, electrical voltages of more than 10,000 V with a simultaneously relatively low space requirement and further requirements in terms of weight, energy consumption and production costs. Such properties are relevant, in particular, to mobile devices, such as augmented reality/virtual reality glasses, in-ear loudspeakers, and also to automotive applications.

A further problem to be solved in the case of space-saving high-voltage components is DC isolation of low-voltage and high-voltage paths in order to ensure functional reliability and long-term stability of a device under changing environmental conditions, for example in terms of a temperature, humidity and dust conditions.

Electrical/magnetic converter devices for a high voltage transformation ratio are known per se from the prior art, but there is the disadvantage that these converter devices suffer from size and/or reliability/stability problems.

An object of the present invention is to provide an improved converter device. This object is achieved by means of a converter device having the features of the independent claim. Advantageous developments are specified in dependent claims.

A converter device comprises a primary coil, a secondary coil and a first semiconductor layer. The primary coil and the secondary coil are each planar, each comprise at least one turn and are arranged coaxially. The primary coil is arranged on an underside of the first semiconductor layer and the secondary coil is arranged on a top side of the first semiconductor layer.

This advantageously provides a cost-effective converter device comprising a small base area and a small volume. In addition, the primary coil and the secondary coil are advantageously DC-isolated from one another. As a result of the fact that the converter device comprises a semiconductor layer, integration with other components can be advantageously carried out. For example, this makes it possible to implement a DC-DC converter with DC isolation. Such a DC-DC converter may be in the form of a flyback converter, for example, and may be provided for the purpose of providing high voltages for operating consumers.

In one embodiment, the converter device comprises a layer sequence having the first semiconductor layer and a second semiconductor layer. The underside of the first semiconductor layer is arranged on a top side of the second semiconductor layer facing the primary coil.

In one embodiment, the converter device comprises a magnetic layer. The magnetic layer is arranged on an underside of the second semiconductor layer. The magnetic layer advantageously forms a magnetic core for guiding and compressing a magnetic field of the primary coil, thus providing a more effective converter device.

In one embodiment, the layer sequence comprises a third semiconductor layer arranged on the top side of the first semiconductor layer. A further magnetic layer is arranged on a top side of the third semiconductor layer. This advantageously makes it possible to improve the efficiency of the converter device. A gap is formed between the magnetic layers. This advantageously makes it possible to store magnetic energy for a short time. This is needed to operate a flyback converter, for example.

In one embodiment, the magnetic layer and/or the further magnetic layer is/are in the form of a ferromagnetic semiconductor layer at least in sections. This advantageously makes it possible to produce particularly thin magnetic layers. Another advantage is that, when producing the converter device, a semiconductor layer is modified in such a manner that a ferromagnetic semiconductor layer is formed on its side facing away from the coils. This also increases a degree of integration of the converter device.

In one embodiment, the ferromagnetic semiconductor layer comprises doping that imparts a ferromagnetic property. A semiconductor material can be provided with ferromagnetic properties, for example, by implanting ions, for example implanting cobalt and/or manganese ions in the case of silicon as the semiconductor material.

In one embodiment, the converter device comprises a controller, a switch and a diode. The controller is provided for the purpose of controlling the switch. The switch is connected in series with the primary coil. The diode is connected in series with the secondary coil. This advantageously provides a flyback converter.

In one embodiment, the controller, the switch and the diode are each integrated in the first semiconductor layer. In another embodiment, the first semiconductor layer is arranged on a substrate. The controller, the switch and the diode are each integrated in the substrate. This advantageously makes it possible to provide in each case a compact and cost-effective flyback converter having a high degree of integration.

In one embodiment, a base area of the primary coil is at least as large as a base area of the secondary coil. This makes it possible to ensure that the secondary coil is arranged completely in a magnetic field of the primary coil when an input voltage is applied to the primary coil. As a result, a particularly efficient voltage conversion can be carried out by means of the converter device.

In one embodiment, the converter device comprises a planar further secondary coil which comprises at least one turn and is arranged coaxially with the primary coil. The secondary coil and the further secondary coil are arranged on opposite sides of the primary coil. A semiconductor layer is respectively arranged between the coils. The secondary coil and the further secondary coil are connected in series with one another. This advantageously makes it possible to provide an output voltage which is composed of a sum of the output voltages of the individual secondary coils, thus making it possible to increase a voltage conversion ratio.

In one embodiment, the converter device comprises a second primary coil and a second secondary coil. The second primary coil and the second secondary coil are each planar, each comprise at least one turn and are arranged coaxially. A semiconductor layer is respectively arranged between the coils. The secondary coil and the second secondary coil are connected in series with one another. This makes it possible to achieve a particularly high voltage conversion ratio. In one embodiment, the primary coil, the second primary coil, the secondary coil and the second secondary coil are arranged coaxially.

In one embodiment, the primary coil and the second primary coil are connected in parallel with one another. This advantageously makes it possible to achieve a low overall primary inductance if this is required.

The above-described properties, features and advantages of this invention and the way in which they are achieved will become clearer and more clearly understood in association with the following description of the exemplary embodiments which are explained in greater detail in association with the drawings, in each of which, in a schematic representation:

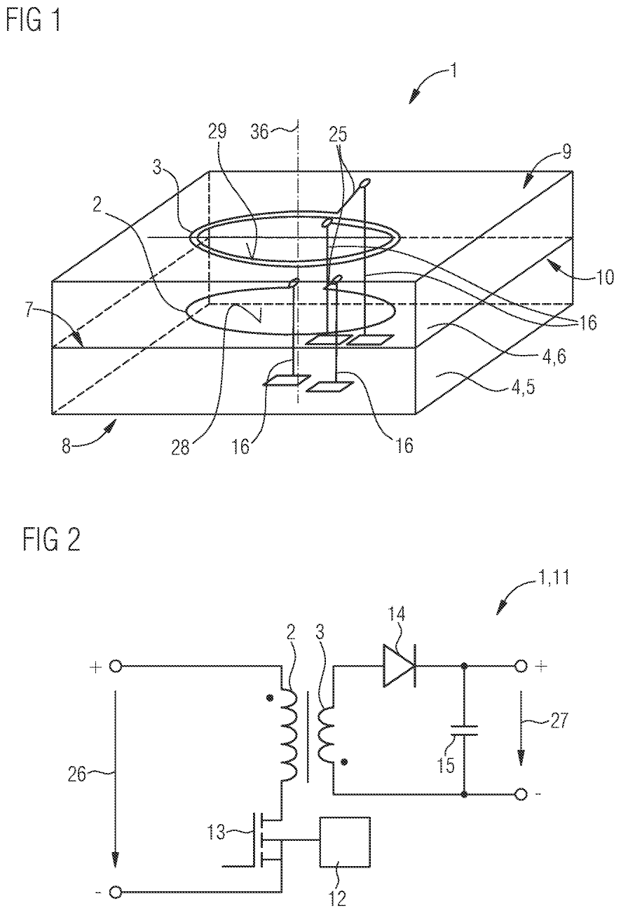

FIG. 1: shows a perspective view of a converter device according to one embodiment;

FIG. 2: shows an electrical circuit of a flyback converter;

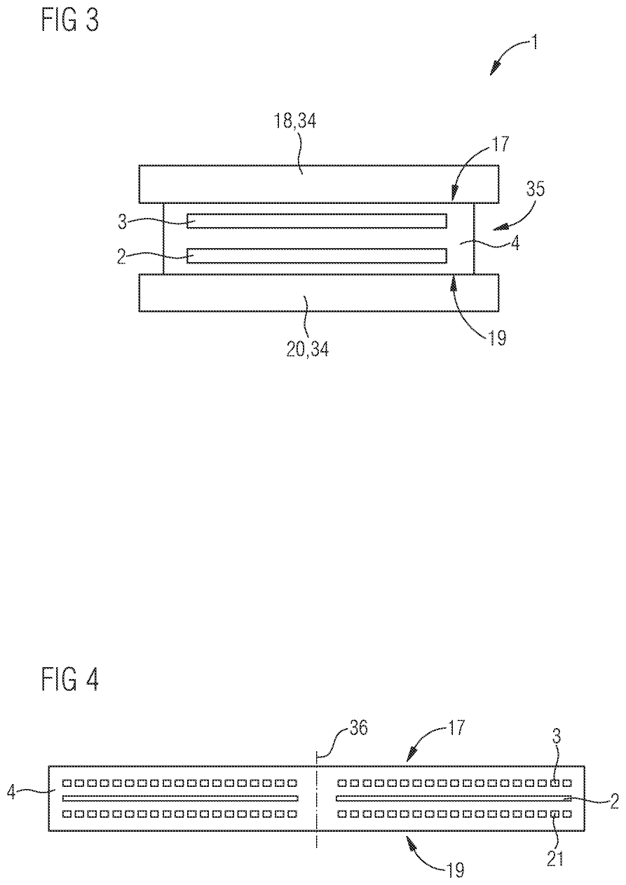

FIG. 3: shows a cross-sectional view of a converter device according to a further embodiment;

FIG. 4: shows a cross-sectional view of a converter device according to a further embodiment;

FIG. 5: shows an electrical circuit of the converter device in FIG. 4;

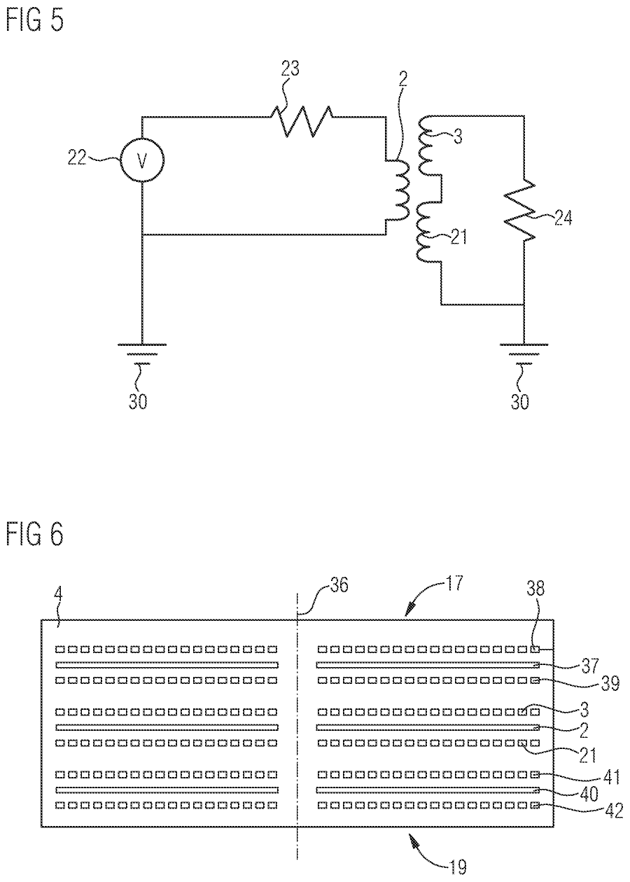

FIG. 6: shows a cross-sectional view of a converter device according to a further embodiment;

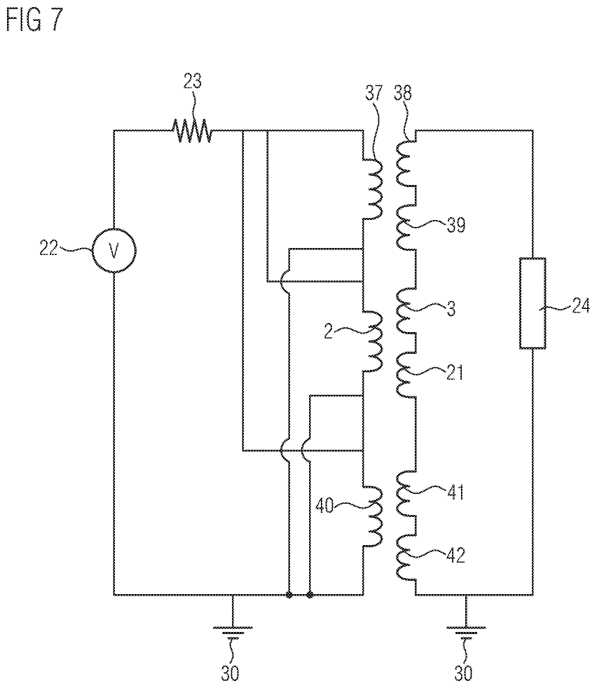

FIG. 7: shows an electrical circuit of the converter device in FIG. 6; and

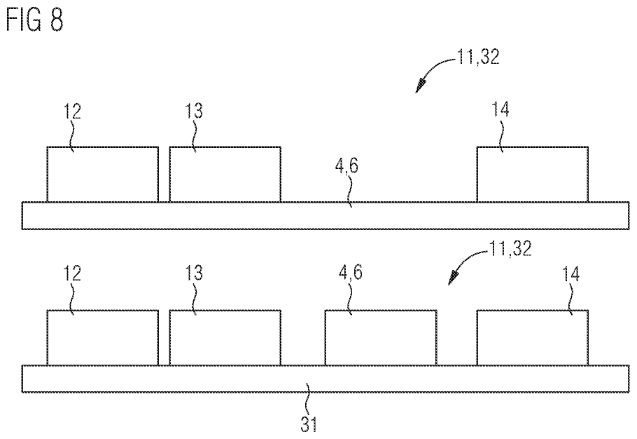

FIG. 8: shows arrangements of two flyback converters.

FIG. 1 schematically shows a perspective view of elements of a converter device 1 according to one embodiment.

The converter device 1 is configured to convert an electrical voltage, wherein the converter device 1 is configured to generate an output voltage on the basis of an input voltage. The converter device 1 may be in the form of a DC-DC converter, for example, but this is not absolutely necessary. If the converter device 1 is in the form of a DC-DC converter, it may be in the form of a flyback converter, for example.

The converter device 1 comprises a primary coil 2 and a secondary coil 3. The primary coil 2 and the secondary coil 3 each comprise a metal, for example gold or copper. However, the primary coil 2 and the secondary coil 3 may each comprise any metal or may each also comprise a metal alloy. The primary coil 2 and the secondary coil 3 are each planar. As a result, the primary coil 2 and the secondary coil 3 each run within a plane. As a result of the fact that the primary coil 2 and the secondary coil 3 are planar, the converter device 1 advantageously comprises a small overall height. The primary coil 2 and the secondary coil 3 are arranged coaxially, that is to say they are arranged in such a manner that they comprise a matching center axis 36.

A number of turns may be arbitrary both in the primary coil 2 and in the secondary coil 3. FIG. 1 shows merely by way of example that the primary coil 2 comprises only one turn and the secondary coil 3 comprises only two turns. It may also be the case, for example, that the primary coil 2 comprises only a few turns and the secondary coil 3 comprises several hundred turns, for example. In another example, the primary coil 2 comprises one turn, whereas the secondary coil 3 comprises one hundred turns. In contrast to the examples mentioned, the primary coil 2 may also comprise more turns than the secondary coil 3. This enables a voltage conversion in which an output voltage is lower than an input voltage. However, a higher number of turns of the secondary coil 3 advantageously enables a voltage conversion in which an output voltage is higher than an input voltage.

The primary coil 2 and the secondary coil 3 may also be referred to as spiral. A turn spacing between turns of the primary coil 2 and the secondary coil 3 may be constant in each case. However, the primary coil 2 and the secondary coil 3 may also each comprise a turn spacing between their turns that increases toward the inside or outside, for example.

The converter device 1 also comprises at least one first semiconductor layer 6. The primary coil 2 is arranged on a first underside 10 of the first semiconductor layer 6. The secondary coil 3 is arranged on a first top side 9 of the first semiconductor layer 6. The primary coil 2 and the secondary coil 3 are arranged coaxially, as a result of which the secondary coil 3 is arranged in a magnetic field of the primary coil 2 when an electrical voltage is applied to the primary coil 2, if a spacing between the primary coil 2 and the secondary coil 3 is selected to be small enough. This spacing also depends, inter alia, on a magnetic field strength. The spacing between the primary coil 2 and the secondary coil 3 may be 10 μm, for example. However, this is only an exemplary statement of a value. The spacing between the coils 2, 3 may also be selected differently.

The exemplary converter device 1 in FIG. 1 comprises a layer sequence 4 having the first semiconductor layer 6 and a second semiconductor layer 5. The first semiconductor layer 6 comprises the first top side 9 and the first underside 10, wherein the first top side 9 and the first underside 10 are opposite one another. The second semiconductor layer 5 comprises a second top side 7 and a second underside 8 opposite the second top side 7. The first underside 10 of the first semiconductor layer 6 in the layer sequence 4 is arranged on the second top side 7 of the second semiconductor layer 5 facing the primary coil 2. In other words, the primary coil 2 is arranged on the second top side 7 of the second semiconductor layer 5 and the secondary coil 3 is arranged on the first top side 9 of the first semiconductor layer 6. In contrast to the representation in FIG. 1, the primary coil 2 may also be arranged on the first top side 9 of the first semiconductor layer 6 and the secondary coil 3 may be arranged on the second top side 7 of the second semiconductor layer 5.

The converter device 1 need not necessarily comprise a layer sequence 4 having a plurality of semiconductor layers 5, 6. It suffices if the converter device 1 comprises at least the first semiconductor layer 6, with the result that the second semiconductor layer 5 and possibly further semiconductor layers may be dispensed with. Conversely, the layer sequence 4 may also comprise more than two semiconductor layers 5, 6. For example, a total of three semiconductor layers 5, 6 may be provided, wherein the primary coil 2 and the secondary coil 3 are each arranged between two semiconductor layers 5, 6.

The semiconductor layers 5, 6 each comprise a semiconductor material. For example, the semiconductor layers 5, 6 may each comprise silicon. However, the semiconductor layers 5, 6 may also comprise another semiconductor. It is expedient that the semiconductor layers 5, 6 each comprise the same semiconductor material. This simplifies a production process.

The primary coil 2 and the secondary coil 3 may be arranged, for example, directly on the first semiconductor layer 6 or may be respectively arranged on the semiconductor layers 5, 6 in the layer sequence 4. The primary coil 2 and the secondary coil 3 may be arranged on the semiconductor layers 5, 6, for example, by means of cathode sputtering or, for example, by means of galvanic deposition. Other known deposition methods may also be used to arrange the primary coil 2 and the secondary coil 3 on the semiconductor layers 5, 6.

The primary coil 2 and the secondary coil 3 may alternatively be, for example, in the form of doped regions which are generated in the semiconductor layers 5, 6 and comprise a significant electrical conductivity. In another embodiment, trenches may first of all be arranged on the undersides and/or top sides 7, 8, 9, 10 of the semiconductor layers 5, 6, in which trenches the primary coil 2 and the secondary coil 3 are arranged.

The layer sequence 4 may be produced, for example, by gradually depositing a semiconductor material. Alternatively, individual semiconductor layers 5, 6 may also be connected to one another by means of a wafer bonding technique, for example by means of silicon direct bonding. In addition to the semiconductor layers 5, 6, the layer sequence 4 may also comprise further intermediate layers which are not shown in FIG. 1 for the sake of simplicity. They may be oxide layers, for example. Other expedient intermediate layers which are known from semiconductor manufacture may likewise be present.

In addition to known deposition methods or wafer bonding techniques, known structuring techniques may also be used when producing the layer sequence 4, for example in order to produce electrical plated through-holes 16 for coils 2, 3, which plated through-holes run vertically through the semiconductor layers 5, 6 and are provided for the purpose of making electrical contact with the coils 2, 3. FIG. 1 additionally illustrates contact-making elements 25 which electrically connect the coils 2, 3 and the plated through-holes 16 to one another. The contact-making elements 25 may also be dispensed with, with the result that the coils 2, 3 are in direct contact with the plated through-holes 16. However, in contrast to the representation in FIG. 1, electrical contact need not necessarily be made with the primary coil 2 and the secondary coil 3 by means of plated through-holes 16, but rather may also be made, for example, using laterally arranged contact-making elements.

Furthermore, structuring techniques may be used when producing the converter device 1. For example, it may be necessary to planarize semiconductor layers 5, 6 or structure them in another manner. Planarization can be carried out, for example, using a chemical-mechanical polishing method. Structuring can be carried out, for example, using photolithography.

As a result of the structure of the converter device 1, it is possible for the secondary coil 3 to be arranged within a magnetic field that is generated when an electrical voltage is applied to the primary coil 2. In this manner, the converter device 1 can transmit electrical energy from the primary coil 2 to the secondary coil 3. A voltage conversion can be expediently carried out. For example, the converter device 1 may be in the form of a DC-DC converter. The converter device 1 may be in the form of a so-called flyback converter, for example. The converter device 1 may also be, for example, in the form of another converter, for example in the form of a forward converter.

FIG. 2 schematically shows an electrical circuit of a converter device 1 in the form of a flyback converter 11. The semiconductor layers 5, 6 are not shown in the illustration in FIG. 2 for the sake of simplicity. The flyback converter 11 is a DC-DC converter having DC-isolated voltage paths. DC isolation is advantageous, in particular, in applications which comprise both low-voltage paths and high-voltage paths.

The flyback converter 11 comprises a controller 12, a switch 13 and a diode 14. The controller 12 may be in the form of a microcontroller, for example, and is provided for the purpose of controlling the switch 13. The switch 13 may be, for example, in the form of a transistor, for example in the form of a metal-oxide-semiconductor field-effect transistor (MOSFET). The switch 13 is connected in series with the primary coil 2. In contrast, the diode 14 is connected in series with the secondary coil 3. An input voltage 26 may be applied on the primary coil side. An output voltage 27 may be tapped off on the secondary coil side. A capacitor 15 connected in parallel with the secondary coil 3 is provided for the purpose of being charged with the output voltage 27.

The capacitor 15 is provided for the purpose of providing a consumer with the output voltage 27. However, the capacitor 15 may also be dispensed with.

The functional principle of a flyback converter 11 is explained briefly below. During a conducting phase with the switch 13 closed, the input voltage 26 is present at the primary coil 2. A primary current and a primary magnetic flux increase during this time, as a result of which magnetic energy is stored in a gap between the primary coil 2 and the secondary coil 3. The diode 14 is operated in the reverse direction by way of a voltage induced in the secondary coil 2.

If the switch 13 is opened, the primary current and the primary magnetic flux fall. The diode 14 is operated in the forward direction by virtue of a voltage induced in the secondary coil 2, thus enabling a current flow. As a result, the capacitor 15 can be charged or another consumer can be supplied, for example. The charged capacitor 15 in turn may be discharged in the conducting phase in order to supply a consumer.

For an efficient voltage conversion, it is favorable if a base area 28 of the primary coil 2 comprises at least a size of a base area 29 of the secondary coil 3. That area which is surrounded by an outermost turn of the relevant coil 2, 3 is intended to be referred to as the base area 28, 29 of a coil 2, 3. This makes it possible for the secondary coil 3 to be arranged completely in a magnetic field of the primary coil 2 when the input voltage 26 is applied to the primary coil 2. A base area of the respective coils may be a few square millimeters, for example. If large voltage conversion ratios are sought, the primary coil 2 must be able to conduct possibly high electrical currents. So that the primary coil 2 does not comprise a high electrical resistance, a cross section of the primary coil 2 should be selected to be large. This also applies to the secondary coil 3.

In addition, an inductance of the coils 2, 3 may be respectively adapted by selecting suitable geometries. The inductance of a planar coil is, for example, proportional to the square of the number of turns and proportional to a mean diameter that is composed of an external diameter of a planar coil and an internal diameter of the planar coil. Furthermore, a filling factor determines the inductance of a planar coil. The filling factor is given by a quotient of a difference between the external diameter and the internal diameter and a sum of the external diameter and the internal diameter.

A magnetic core in the region between the coils 2, 3 is indicated in FIG. 2. A magnetic core is a magnetic body having a high magnetic permeability, for example, that is typically used to include and guide magnetic fields in electrical, electromechanical and magnetic devices such as electromagnets, transformers, electric motors and generators. In the case of AC transformers, a magnetic core is self-contained and does not comprise a gap. However, a flyback converter 11, for example, requires a magnetic core with a gap. A space between two opposite faces, which guide a magnetic flux, is referred to as a gap, or an air gap, in electrical engineering in the context of magnetic cores.

FIG. 3 schematically shows a cross-sectional view of elements of a converter device 1 according to a further embodiment. The converter device 1 in FIG. 3 comprises similarities to the converter device 1 in FIG. 1. Similar or identical elements are provided with the same reference signs for this reason. FIG. 3 shows an implementation of the principle of a magnetic core on the planar converter device 1.

In the converter device 1 in FIG. 3, the primary coil 2 and the secondary coil 3 are each completely embedded within the layer sequence 4, for example. The individual semiconductor layers 5, 6 are not shown for the sake of simplicity. Three or more semiconductor layers 5, 6 arranged on top of one another may be provided, wherein the primary coil 2 and the secondary coil 3 are each arranged between two semiconductor layers 5, 6.

A first magnetic layer 18 is arranged on a top side 17 of the layer sequence 4. The first magnetic layer 18 is arranged, for example, on a top side of a third semiconductor layer if the layer sequence 4 comprises only three semiconductor layers 5, 6. A second magnetic layer 20 is arranged on an underside 19 of the layer sequence 4. The second magnetic layer 20 is arranged, for example, on the second underside 8 of the second semiconductor layer 5 if the layer sequence 4 comprises only three semiconductor layers 5, 6. In any case, a magnetic layer 18, 20 is separated from the coils 2, 3 by at least one semiconductor layer 5, 6.

The magnetic layers 18, 20 may each comprise a ferromagnetic material, for example. However, it is conceivable for the magnetic layers 18, 20 to each also comprise another magnetic material. A ferromagnetic material offers the advantage that it can guide and concentrate magnetic fields. A ferromagnetic material offers the advantage that eddy current losses can be reduced, which may be advantageous in AC voltage applications or applications with a high switching frequency. This makes it possible to increase an efficiency of a voltage conversion. In addition, the first magnetic layer 18 and the second magnetic layer 20 form a magnetic core 34 having a gap 35. The gap 35 is formed between the magnetic layers 18, 20. The gap 35 is advantageously suitable for storing magnetic energy, thus making it possible to implement a flyback converter 11.

The magnetic layers 18, 20 may be in the form of semiconductor layers that are ferromagnetic at least in sections, for example, but this is not absolutely necessary. A ferromagnetic semiconductor layer comprises doping that imparts ferromagnetic properties, for example. A semiconductor material can be magnetized by means of ion implantation, for example. If silicon is used as the semiconductor material, a ferromagnetic semiconductor layer may be produced, for example, by implanting cobalt and/or manganese ions. Other combinations of semiconductor ions are also conceivable.

During the ion implantation of crystalline silicon, a ferromagnetic semiconductor layer that comprises the implanted ions is produced on the crystalline silicon. An amorphous semiconductor layer that can be produced during ion implantation may be formed on the ferromagnetic semiconductor layer. If the converter device 1 is in the form of a flyback converter 11, no magnetic regions should expediently be formed at least in the gap 35 or in a region between the primary coil 2 and the secondary coil 3, since they make it difficult to store magnetic energy.

However, it is not absolutely necessary for the converter device 1 to comprise the magnetic layers 18, 20. The magnetic layers 18, 20 may also be dispensed with. Alternatively, the converter device 1 may also comprise only one magnetic layer 18, 20. In this case, either the second magnetic layer 20 or the first magnetic layer 18 may be dispensed with. In the case of only one magnetic layer 18, 20, it is not absolutely necessary to provide a total of three semiconductor layers. Referring to FIG. 1, in the case of only two semiconductor layers 5, 6, only the second magnetic layer 20 could be arranged on the underside 19 of the layer sequence 4 or on the underside 8 of the second semiconductor layer 5.

FIG. 4 schematically shows a cross-sectional view of elements of a converter device 1 according to a further embodiment. The converter device 1 in FIG. 4 comprises similarities to the converter device 1 in FIG. 1. Similar or identical elements are provided with the same reference signs for this reason. The semiconductor layers 5, 6 in the layer sequence 4 are again not individually shown for the sake of simplicity.

The converter device in FIG. 4 comprises a planar further secondary coil 21 comprising at least one turn. Merely by way of example, the primary coil 2 comprises only one turn, whereas the secondary coil 3 and the further secondary coil 21 each comprise nineteen turns, for example. The secondary coil 3 and the further secondary coil 21 are arranged on opposite sides of the primary coil 2. The further secondary coil 21 and the primary coil 2 are arranged coaxially. It is advantageous if the base area 28 of the primary coil 2 comprises at least a size of the base area 29 of the further secondary coil 21, as shown in FIG. 4.

A semiconductor layer 5, 6 is respectively arranged between the primary coil 2 and the secondary coil 3 and between the primary coil 2 and the further secondary coil 21. In the example shown, it is possible to provide a total of four semiconductor layers 5, 6, for example, which are arranged against one another or on top of one another, wherein the coils 2, 3, 21 are respectively arranged between two semiconductor layers 5, 6. However, a number of the semiconductor layers 5, 6 is not restricted to the number mentioned. The important factor is only that the semiconductor layers 5, 6 separate the coils 2, 3, 21 from one another, that is to say at least two semiconductor layers 5, 6 are provided in this case. Referring to the embodiment in FIG. 1, the further secondary coil 21 could be arranged, for example, on the underside 8 of the second semiconductor layer 5. A spacing between the coils 2, 3, 21 may be 10 μm in each case, for example. However, this is only an exemplary statement of a value. Spacings between the coils 2, 3, 21 may also be less than or greater than 10 μm.

The converter device 1 in FIG. 4 may also comprise one magnetic layer 18, 20 or both magnetic layers 18, 20 which are arranged either on the underside 19 and/or on the top side 17 of the layer sequence 4, but this is not absolutely necessary. In this case too, the first magnetic layer 18 and/or the second magnetic layer 20 may each be in the form of semiconductor layers that are ferromagnetic at least in sections.

FIG. 5 schematically shows an electrical circuit of the converter device 1 in FIG. 4.

The primary coil 2 is connected to a voltage source 22. A protective resistor 23 is connected in series with the primary coil 2. However, the protective resistor 23 may also be dispensed with. The secondary coil 3 and the further secondary coil 21 are connected in series with one another and in series with a load resistor 24 or a load 24. The load 24 is only optional and may also be dispensed with. The converter device 1 is grounded, that is to say connected to ground 30, both on the primary side and on the secondary side, but this is not absolutely necessary. As a result of the series circuit of the secondary coils 3, 21, their respective output voltages 27 are added, as a result of which a larger summation output voltage can be advantageously generated overall. In order to make electrical contact with and interconnect the secondary coils 3, 21 connected in series, the converter device 1 may comprise electrical plated through-holes 16, for example.

FIG. 6 schematically shows a cross-sectional view of elements of a converter device 1 according to a further embodiment. The converter device 1 in FIG. 6 comprises similarities to the converter device 1 in FIG. 4. Similar or identical elements are provided with the same reference signs for this reason. The semiconductor layers 5, 6 in the layer sequence 4 are again not shown for the sake of simplicity.

In addition to the primary coil 2, the converter device 1 comprises a second primary coil 37 and a third primary coil 40. However, the converter device 1 may also comprise only the primary coil 2 and the second primary coil 37, for example. Alternatively, the converter device 1 may also comprise more than three primary coils 2, 37, 40. In addition to the secondary coil 3, the converter device 1 comprises a second secondary coil 38 and a third secondary coil 41. However, the converter device 1 may also comprise only the secondary coil 3 and the second secondary coil 37, for example. Alternatively, the converter device 1 may also comprise more than three primary coils 2, 37, 40.

In the exemplary illustration in FIG. 6, a secondary coil 3, 38, 41 and a further secondary coil 21, 39, 42 are respectively provided for each primary coil 2, 37, 40. However, a further secondary coil 3, 38, 41 need not necessarily be provided for each primary coil 2, 37, 40. A primary coil 2, 37, 40, an associated secondary coil 3, 38, 41 and an associated further secondary coil 21, 39, 42 respectively form a coil group. Three coil groups are arranged on top of one another. However, fewer or more than three such coil groups may also be arranged on top of one another. The converter device 1 may alternatively comprise coil groups which are arranged on top of one another, for example, and each comprise only one primary coil 2, 37, 40 and only one secondary coil 3, 38, 41 and each do not comprise any further secondary coil 21, 39, 42. In this case, primary coils 2, 37, 40 and secondary coils 3, 38, 41 are alternately arranged on top of one another. The converter device 1 may also comprise different coil groups.

The primary coils 2, 37, 40, the secondary coils 3, 38, 41 and the further secondary coils 21, 39, 42 are each planar, each comprise at least one turn and are arranged coaxially. However, not all coils 2, 3, 37, 38, 39, 40, 41, 42 need to be arranged coaxially. It may suffice, however, if at least coils 2, 3, 37, 38, 39, 40, 41, 42 in a respective coil group are arranged coaxially. However, a coaxial arrangement of all coils 2, 3, 37, 38, 39, 40, 41, 42 offers the advantage that the converter device 1 comprises a small base area.

Merely by way of example, the primary coils 2, 37, 40 each comprise only one turn, whereas the secondary coils 3, 21, 41 and the further secondary coils 21, 39, 42 each comprise eighteen turns, for example. A secondary coil 3, 38, 40 and a further secondary coil 21, 39, 42 are each arranged on opposite sides of a primary coil 2, 37, 40. It is advantageous if the base area 28 of the primary coils 2 in each case comprises at least a size of the base area 29 of the secondary coils 3, 21.

A semiconductor layer 5, 6 is respectively arranged between the primary coils 2, 37, 40 and the secondary coils 3, 38, 41 and between the primary coils 2, 37, 40 and the further secondary coils 21, 39, 42. In the example shown, it is possible to provide a total of ten semiconductor layers 5, 6, for example, which are arranged against one another or on top of one another, wherein the coils 2, 3, 37, 38, 39, 40, 41, 42 are respectively arranged between two semiconductor layers 5, 6. However, a number of the semiconductor layers 5, 6 is not restricted to the number mentioned. The important factor is only that the semiconductor layers 5, 6 separate the coils 2, 3, 37, 38, 39, 40, 41, 42 from one another.

The converter device 1 in FIG. 6 may also comprise one magnetic layer 18, 20 or both magnetic layers 18, 20 which are arranged either on the underside 19 and/or on the top side 17 of the layer sequence 4, but this is not absolutely necessary. In this case too, the first magnetic layer 18 and/or the second magnetic layer 20 may be in the form of semiconductor layers that are ferromagnetic at least in sections.

FIG. 7 schematically shows an electrical circuit of the converter device 1 in FIG. 6.

The primary coils 2, 37, 40 are each connected to a voltage source 22. An optional protective resistor 23 is connected in series with the primary coils 2, 37, 40 and may also be dispensed with. The secondary coils 3, 21, 38, 39, 41, 42 are connected in series with one another and with a load 24, wherein the load 24 may also be dispensed with. As a result of the series circuit of the secondary coils 3, 21, 38, 39, 41, 42, their respective output voltages are added, as a result of which larger summation output voltages can be generated overall. In order to make electrical contact with and interconnect the secondary coils 3, 21, 38, 39, 41, 42 connected in series, the converter device 1 may comprise, as already explained, electrical plated through-holes 16, for example. The converter device 1 is connected to ground 30 both on the primary side and on the secondary side, but this is not absolutely necessary.

The primary coils 2, 37, 40 are connected in parallel with one another, for example, as a result of which a larger summation output voltage can be generated. However, the primary coils 2, 37, 40 may also be connected in series with one another, for example, in order to obtain a higher primary inductance.

The converter devices 1 in FIG. 1, FIG. 3, FIG. 4 and FIG. 6 have the advantage that they enable integration with other electronic components. For example, the converter device 1 may be integrated together with further components of a flyback converter 11, that is to say at least the controller 12, the switch 13 and the diode 14. This can be achieved in two different ways.

FIG. 8 schematically shows geometrical arrangements of two different flyback converters 11, 32, 33. In a first variant 32, the controller 12, the switch 13 and the diode 14 are each integrated in the at least first semiconductor layer 6 or alternatively in the layer sequence 4. In another, second variant 33, the at least one first semiconductor layer 6 or the layer sequence 4 is arranged on a substrate 31. The controller 12, the switch 13 and the diode 14 are each integrated in the substrate 31. The substrate 31 may comprise silicon, for example. This enables particularly simple integration.

The term “integrated” should be understood as meaning the fact that the elements mentioned are arranged either at, above or on the substrate 31 and possibly with the use of intermediate layers, or are embedded in the substrate 31 at least in sections. For example, a MOSFET may comprise doped areas, which are embedded in a substrate 31, for its electrical connections.

A converter device 1 may comprise a diameter of 5 mm, for example. A thickness of a converter device 1 depends substantially on a thickness of the first semiconductor layer 6 or of the layer sequence 4 of semiconductor layers 5, 6. It may be less than 1 mm, for example. The indications of values should be understood merely as an example and should not be understood as restricting the converter device 1.

A converter device 1 can be used to achieve high voltage conversion rates; for example, a voltage conversion rate of more than seventy can be achieved for a component area of the converter device 1 of 10 mm², that is to say the output voltage 27 or the summation output voltage is seventy times greater than the input voltage 26. For example, a voltage conversion rate of more than two hundred can be achieved for a component volume of the converter device 1 of significantly less than 25 mm³ by stacking coils 2, 3, 21, 37, 38, 39, 40, 41, 42 and by way of series circuits of secondary coils 3, 21.

The invention was described and illustrated more specifically using the preferred exemplary embodiments. However, the invention is not restricted to the disclosed examples. Rather, other variants can be derived therefrom by a person skilled in the art without going beyond the scope of protection of the invention.

### LIST OF REFERENCE SIGNS

1 Converter device
2 Primary coil
3 Secondary coil
4 Layer sequence
5 First semiconductor layer
6 Second semiconductor layer
7 Second top side of the second semiconductor layer
8 Second underside of the second semiconductor layer
9 First top side of the first semiconductor layer
10 First underside of the first semiconductor layer
11 Flyback converter
12 Controller
13 Switch
14 Diode
15 Capacitor
16 Plated through-hole
17 Top side of the layer sequence
18 Second magnetic layer
19 Underside of the layer sequence
20 First magnetic layer
21 Further secondary coil
22 Voltage source
23 Protective resistor
24 Load
25 Contact-making elements
26 Input voltage
27 Output voltage
28 Base area of the primary coil
29 Base area of the secondary coil
30 Ground
31 Substrate
32 First variant of a flyback converter
33 Second variant of a flyback converter
34 Magnetic core
35 Gap
36 Center axis
37 Second primary coil
38 Second secondary coil
39 Second further secondary coil
40 Third primary coil
41 Third secondary coil
42 Third further secondary coil

1. A converter device,
comprising a primary coil, a secondary coil and a first semiconductor layer,
wherein the primary coil and the secondary coil are each planar, each comprise at least one turn and are arranged coaxially,
wherein the primary coil is arranged on an underside of the first semiconductor layer and the secondary coil is arranged on a top side of the first semiconductor layer.

2. The converter device according to claim 1,
comprising a layer sequence having the first semiconductor layer and a second semiconductor layer,
wherein the underside of the first semiconductor layer is arranged on a top side of the second semiconductor layer facing the primary coil.

3. The converter device according to claim 2,
having a first magnetic layer,
wherein the first magnetic layer is arranged on an underside of the second semiconductor layer.

4. The converter device according to claim 3,
wherein the layer sequence comprises a third semiconductor layer arranged on the top side of the first semiconductor layer,
wherein a second magnetic layer is arranged on a top side of the third semiconductor layer.

5. The converter device according to claim 4, wherein the first magnetic layer and/or the second magnetic layer is/are in the form of a ferromagnetic semiconductor layer at least in sections.

6. The converter device according to claim 5,
wherein the ferromagnetic semiconductor layer comprises doping that imparts ferromagnetic properties.

7. The converter device according to claim 1,
having a controller, a switch and a diode,
wherein the controller is provided for the purpose of controlling the switch,
wherein the switch is connected in series with the primary coil,
wherein the diode is connected in series with the secondary coil.

8. The converter device according to claim 7,
wherein the controller, the switch and the diode are each integrated in the first semiconductor layer.

9. The converter device according to claim 7,
wherein the first semiconductor layer is arranged on a substrate,
wherein the controller, the switch and the diode are each integrated in the substrate.

10. The converter device according to claim 1,
wherein a base area of the primary coil is at least as large as a base area of the secondary coil.

11. The converter device according to claim 2,
having a planar further secondary coil which comprises at least one turn and is arranged coaxially with the primary coil,
wherein the secondary coil and the further secondary coil are arranged on opposite sides of the primary coil,
wherein a semiconductor layer is respectively arranged between the coils,
wherein the secondary coil and the further secondary coil are connected in series with one another.

12. The converter device according to claim 2,
comprising a second primary coil and a second secondary coil,
wherein the second primary coil and the second secondary coil are each planar, each comprise at least one turn and are arranged coaxially,
wherein a semiconductor layer is respectively arranged between the coils,
wherein the secondary coil and the second secondary coil are connected in series with one another.

13. The converter device according to claim 12,
wherein the primary coil and the second primary coil are connected in parallel with one another.
